(19) United States
(12) Patent Application Publication
(10) Pub. No.: US 2026/0364911 A1
(43) Pub. Date: Nov. 19, 2026

(54) PRESS APPARATUS, PRESS ROD UNIT AND UPPER MOLD ASSEMBLY

(71) Applicant: ALL RING TECH CO., LTD., Kaohsiung City (TW)

(72) Inventors: Tai-Hung LIU, Kaohsiung City (TW); Wei-Yang CHANG, Kaohsiung City (TW)

(21) Appl. No.: 19/427,315

(22) Filed: Dec. 19, 2025

(30) Foreign Application Priority Data
May 15, 2025 (TW) 114118305
May 15, 2025 (TW) 114204919

(51) Int. Cl. B30B 15/06; B30B 15/02; H10P 72/00

(52) U.S. Cl. CPC B30B 15/062; B30B 15/02; B30B 15/068; H10P 72/0438

(57) ABSTRACT

A press rod unit includes a pressing rod, a pressing block, at least one fixing member and at least one adjusting member. The pressing rod includes a rod body and a pressing seat disposed at one end of the rod body and having a connecting surface and a sunken portion. The pressing block is disposed on the connecting surface of the pressing seat and is deformable to partially extend into the sunken portion. The at least one fixing member fastens the pressing block to the connecting surface. The at least one adjusting member is operable for adjusting a degree of deformation of the pressing block in the sunken portion.

### CROSS-REFERENCE TO RELATED APPLICATION

This application claims priority to Taiwanese Invention Patent Application No. 114118305, filed on May 15, 2025, and Taiwanese Utility Model Patent Application No. 114204919, filed on May 15, 2025, the entire disclosures of which are incorporated by reference herein.

### FIELD

The disclosure relates to a press rod unit, an upper mold assembly, and a press apparatus, and more particularly to a press rod unit, an upper mold assembly, and a press apparatus for pressing an integrated circuit component covered with a lid.

### BACKGROUND

In the packaging process of integrated circuit components, a conventional press apparatus includes an upper mold device and a lower mold device, and is provided to press a lid onto an integrated circuit component. The upper mold device includes a press rod assembly and an upper mold seat. The press rod assembly includes a pressing rod, and a pressing block mounted to one end of the pressing rod and for pressing against the lid. The lower mold device includes a lower mold seat, and a lower mold module mounted to the lower mold seat and including a lower mold block that is for supporting the integrated circuit component thereon. The upper mold is driven by a first driving force to move downwardly relative to the lower mold device, causing the pressing block to press against the lid. Then, the press rod assembly is driven by a second driving force to move downwardly relative to the upper mold seat, such that the pressing block exerts a force on the lid toward the integrated circuit component.

Referring to FIGS. 13 and 14, for example, a to-be-pressed object includes an integrated circuit component (W2′) placed on a lower mold module 1 and a lid (W1′) covering the integrated circuit component (W2′). The lid (W1′) may be, for example, a heat sink. The integrated circuit component (W2′) may include, for example, a chip (W21′) and a substrate (W22′) that carries the chip (W21′) thereon and that is placed on a lower mold block of the lower mold module 1. A thermal interface material (W3′) is disposed between the lid (W1′) and the chip (W21′) for heat dissipation. An adhesive material (W4′) may be disposed between an outer periphery of the lid (W1′) and the substrate (W22′) to connect the lid (W1′) and the substrate (W22′). A press rod assembly 2 of a conventional press apparatus includes a pressing block 21 and a pressing rod 22 mounted on an upper side of the pressing block 21. The pressing rod 22 includes a rod body 221 and a pressing seat 222 that has a width greater than a width of the rod body 221. Generally, bottom surfaces of the pressing block 21 and the pressing seat 222 are parallel to top surfaces of the lower mold module 1 and the lid (W1′). When a first driving force (F1′) is applied to the press rod assembly 2, the bottom surface of the pressing block 21 presses against the top surface of the lid (W1′). When a second driving force (F2′) is applied to the press rod assembly 2, the pressing block 21 exerts a force evenly on the lid (W1′) toward the integrated circuit component (W2′).

However, during the pressing process, since an outer periphery of the pressing seat 222 is thinner than a combination of a central part of the pressing seat 222 and the rod body 221 which is connected to the central part, when the press rod assembly 2 is driven to move downwardly by the second driving force (F2′), the outer periphery of the pressing seat 222 may bend upwardly relative to the central part (see FIG. 15), causing deformation of the pressing block 21. That is to say, the pressing block 21 and the pressing seat 222 are susceptible to deforming into a concave surface facing upward and a convex surface facing downward. Furthermore, during the pressing process, the lid (W1′) and/or the integrated circuit component (W2′) are usually heated, which may cause the pressing seat 222 to expand and increase deformation of the pressing block 21 and the pressing seat 222. Consequently, referring to FIG. 16, when the pressing block 21 is driven to press against the lid (W1′), the top surface of the lid (W1′) may deform into a concave surface facing upward and a convex surface facing downward, and thus undesirably pressing the chip (W21′), which may damage the chip (W21′). Furthermore, the outer periphery of the lid (W1′) may be detached from the substrate (W22′), and poor packaging may result.

### SUMMARY

Therefore, an object of the present disclosure is to provide a press rod unit, an upper mold assembly, and a press apparatus that can alleviate at least one of the drawbacks of the prior art.

According to an aspect of the disclosure, a press rod unit includes a pressing rod, a pressing block, at least one fixing member, and at least one adjusting member. The pressing rod includes a rod body and a pressing seat disposed at one end of the rod body and having a connecting surface and a sunken portion. The pressing block is disposed on the connecting surface of the pressing seat and is deformable to partially extend into the sunken portion. The at least one fixing member fastens the pressing block to the connecting surface. The at least one adjusting member is operable for adjusting a degree of deformation of the pressing block in the sunken portion.

According to another aspect of the disclosure, an upper mold assembly includes an upper mold is provided to include at least one press mold mechanism, and an upper mold seat that is for mounting of the at least one press mold mechanism. The at least one press mold mechanism includes the press rod unit as described above.

According to still another aspect of the disclosure, a press apparatus is provided, and is adapted for pressing at least one to-be-pressed object including an integrated circuit component and a lid that covers the integrated circuit component. The press apparatus includes a lower mold assembly and an upper mold assembly. The lower mold assembly includes at least one lower mold module adapted for supporting the integrated circuit component thereon. The upper mold assembly includes at least one press rod unit as described above. The pressing block of the at least one press rod unit is adapted for pressing the lid of the at least one to-be-pressed object toward the integrated circuit component.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a sectional view illustrating a to-be-pressed object to be processed by a press apparatus of an embodiment according to the present disclosure, the to-be-pressed object including an integrated circuit component and a lid covering the integrated circuit component.

FIG. 2 is a partly exploded perspective view illustrating the integrated circuit component including a substrate, a chip disposed on the substrate, a plurality of adhesive materials disposed on four corners of the substrate, a thermal interface material disposed on the chip, and a lid covering the substrate.

FIG. 3 is a partly exploded perspective view illustrating a plurality of to-be-pressed objects to be processed arranged in a matrix on a boat.

FIG. 4 is a perspective view of the press apparatus of the embodiment for pressing the to-be-pressed objects disposed on the boat.

FIG. 5 is a front view illustrating an upper mold assembly and a lower mold assembly of the press apparatus of the embodiment.

FIG. 6 is a perspective view illustrating a press mold mechanism of the upper mold assembly.

FIG. 7 is a perspective view illustrating a press rod unit of the press mold mechanism.

FIG. 8 is a sectional view taken along line VIII-VIII in FIG. 7.

FIG. 9 is a partly exploded perspective view illustrating the press rod unit including a pressing rod and a pressing block.

FIG. 10 is a fragmentary perspective view of the pressing seat and the pressing rod of the pressing rod unit, and the pressing rod unit being disposed upside down.

FIG. 11 is a fragmentary schematic side view illustrating the pressing block disposed above the to-be-pressed object, and the pressing block being deformed and formed with a concave surface facing downwardly.

FIG. 12 is a fragmentary schematic side view illustrating the pressing block pressing against the lid toward the integrated circuit component.

FIG. 13 is a fragmentary schematic side view illustrating a conventional press apparatus for pressing a to-be-pressed object, and a pressing block of the conventional press apparatus disposed above the to-be-pressed object.

FIG. 14 is a fragmentary schematic side view illustrating the pressing block of the conventional press apparatus pressing against a lid toward an integrated circuit component of the to-be-pressed object.

FIG. 15 is a fragmentary schematic side view illustrating the pressing block of the conventional press apparatus being deformed with a concave surface facing upwardly and a convex surface facing downwardly.

FIG. 16 is a fragmentary schematic side view illustrating the pressing block of the conventional press apparatus pressing against the lid toward the integrated circuit component.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

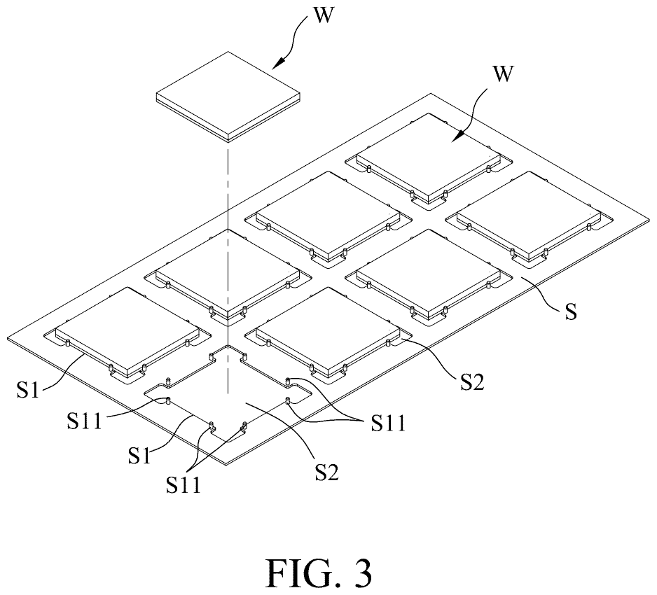

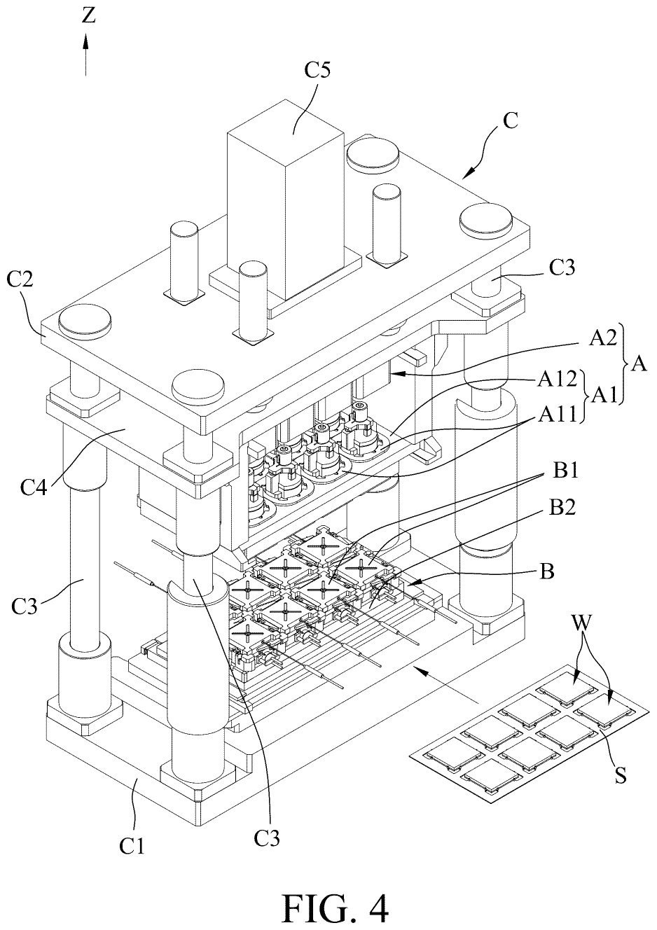

Referring to FIGS. 3 and 4, a press apparatus of an embodiment according to the present disclosure is adapted to press a plurality of to-be-pressed objects (W) carried on a boat (S). The boat (S) may be conveyed to the press apparatus. As shown in FIG. 2, the boat (S) is generally rectangular and includes a plurality of placement areas (S1) that are arranged as a matrix, and a plurality of slots (S2) respectively corresponding in position to the placement areas (S1). The placement areas (S1) are respectively for mounting the to-be-pressed objects (W) thereon. Each of the placement areas (S1) is surrounded by a plurality of positioning pins (S11).

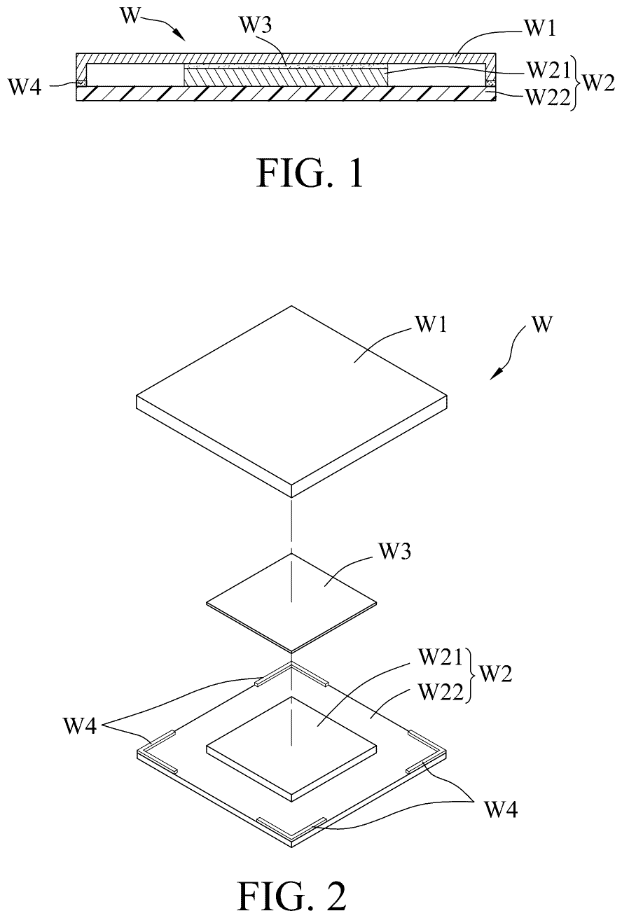

Referring to FIGS. 1 and 2, each of the to-be-pressed objects (W) includes an integrated circuit component (W2) and a lid (W1), which is a heatsink, or a heat slug, covered on the integrated circuit component (W2). The integrated circuit component (W2) includes a substrate (W22) and a chip (W21) disposed on the substrate (W22). The chip (W21) may include, for example, a single or multiple dies, or a single or multiple chips combined with a wiring board such as an intermediate layer and a redistribution layer (RDL) interposer to form a chip stack structure such as a chip on wafer (CoW). The substrate (W22) may be, for example, a printed circuit board (PCB). Each of the to-be-pressed objects (W) further includes a thermal interface material (TIM) (W3) disposed on a top surface of the chip (W21) for heat conduction between the chip (W21) and the lid (W1). The thermal interface material (W3) may be, for example, a thermal interface film, e.g., a film TIM, a metal thermal interface material, e.g., a metal TIM, or a liquid metal thermal interface material, e.g., a liquid metal TIM. The thermal interface material (W3) may be, for example, a composite material made of materials such as indium, graphite, silicon, gold, silver, copper, tin, lead, etc. Each of the to-be-pressed objects (W) further includes a plurality of adhesive materials (W4) disposed on a top surface of the substrate (W22) for connecting the substrate (W22) and the lid (W1). The adhesive materials (W4) may be, for example, a thermosetting adhesive.

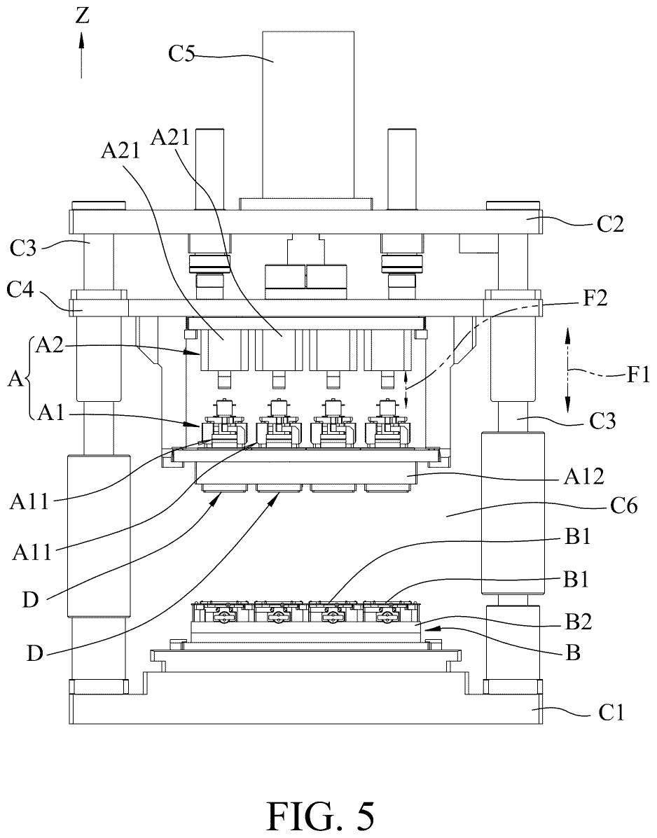

Referring to FIGS. 4 and 5, the press apparatus of the embodiment includes an upper mold assembly (A), a lower mold assembly (B), and a frame seat (C).

The upper mold assembly (A) and the lower mold assembly (B) are spaced apart in an up-down direction (Z) and are mounted on the frame seat (C). The frame seat (C) includes a base (C1), a top plate (C2), a plurality of pillars (C3) interconnecting the base (C1) and the top plate (C2), a movable seat (C4) connected to the pillars (C3), and an upper mold driver (C5) mounted on the top plate (C2). The movable seat (C4) may be driven by a first driving force (F1) provided by the upper mold driver (C5) to move along the pillars (C3) in the up-down direction (Z) in a large distance. The movable seat (C4) and the base (C1) cooperatively define an operating space (C6) therebetween.

The upper mold assembly (A) is disposed in the operating space (C6) and has an upper portion disposed under the movable seat (C4). The upper mold assembly (A) is co-movable with the movable seat (C4) and is movable in the up-down direction (Z) relative to the lower mold assembly (B). The upper mold assembly (A) includes an upper mold module (A1) disposed under the movable seat (C4) and a driver device (A2) mounted to the movable seat (C4) and disposed above the upper mold module (A1). The upper mold module (A1) includes a plurality of press mold mechanisms (A11) arranged as a matrix and an upper mold seat (A12) for mounting of the press mold mechanisms (A11) thereon. Each of press mold mechanisms (A11) includes a press rod unit (D). The driver device (A2) includes a plurality of pressing rod drivers (A21) arranged as a matrix and respectively registered with the press mold mechanisms (A11) in the up-down direction (Z). Each of the pressing rod drivers (A21) is operable to drive the press rod unit (D) of the respective one of the press mold mechanisms (A11) with a second force (F2) to move the press rod unit (D) in a small distance relative to the upper mold seat (A12) in the up-down direction (Z). The small distance is smaller than the large distance.

The lower mold assembly (B) is disposed in the operating space (C6) and is disposed on the base (C1). The lower mold assembly (B) includes a plurality of lower mold modules (B1) arranged as a matrix and a lower mold seat (B2) for mounting of the lower mold modules (B1) thereon. The lower mold modules (B1) may extend respectively through the slots (S2) of the boat (S) (see FIG. 3) and respectively support the to-be-pressed objects (W) thereon. In other words, the substrate (W22) of each of the integrated circuit components (W2) (FIG. 1) is disposed on the respective one of the lower mold modules (B1). Since the structures of the press mold mechanisms (A11) are identical and the structures of the pressing rod drivers (A21) are identical, only one of the press mold mechanisms (A11) and the respective one of the pressing rod drivers (A21) will be described in the following for the sake of brevity.

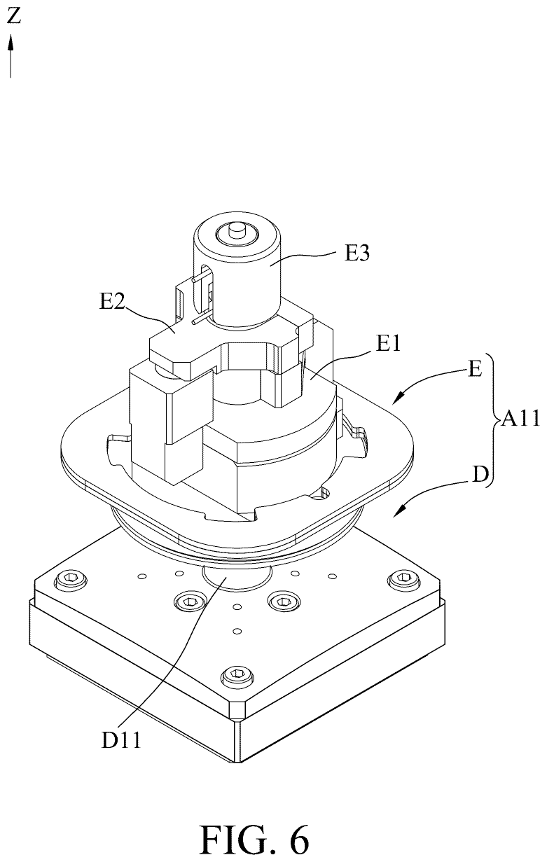

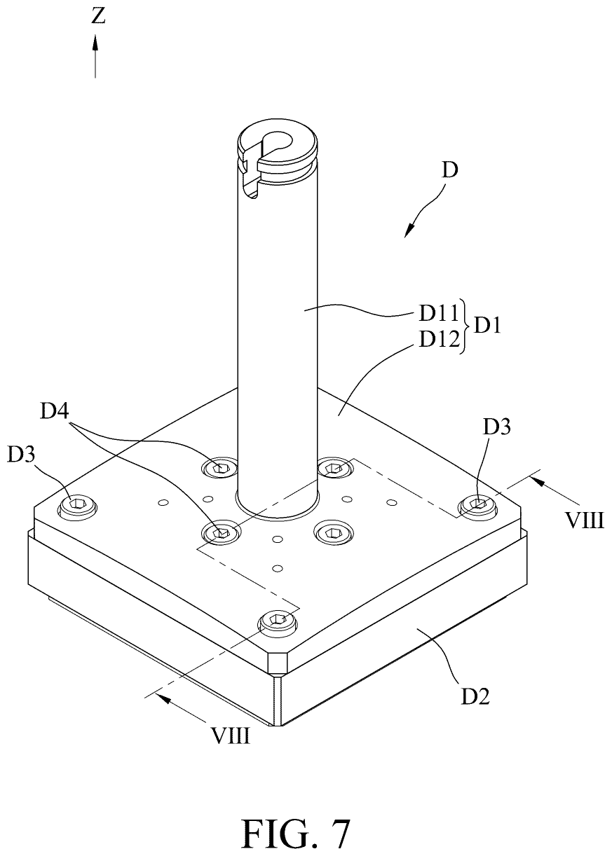

Referring to FIGS. 6 and 7, the press mold mechanism (A11) also includes a limit unit (E) that is mounted to the press rod unit (D). The limit unit (E) is provided to limit movement of the press rod unit (D) in a transverse plane normal to the up-down direction (Z) and to limit rotation of the press rod unit (D) about a rotation axis parallel to the up-down direction (Z). In this embodiment, the press rod unit (D) is movable in the up-down direction (Z) relative to the limit unit (E).

The press rod unit (D) includes a pressing rod (D1) and a pressing block (D2). The pressing rod (D1) includes a rod body (D11) and a pressing seat (D12) disposed at one end of the rod body (D11). The pressing block (D2) is disposed on the pressing seat (D12) and is operable to press the lid (W1) (see FIG. 1).

The limit unit (E) includes a pivot seat (E1) for mounting of the rod body (D11), a limit seat (E2) disposed above the pivot seat (E1) in the up-down direction (Z), and a pressure sensor (E3) disposed on an upper portion of the rod body (D11). The limit seat (E2) is provided to limit rotation of the rod body (D11). The pressure sensor (E3) is configured to sense a force applied by the pressing rod driver (A21) (see FIG. 5). Since the main feature of the present disclosure does note reside in the limit unit (E), further details of the same are not described for the sake of brevity.

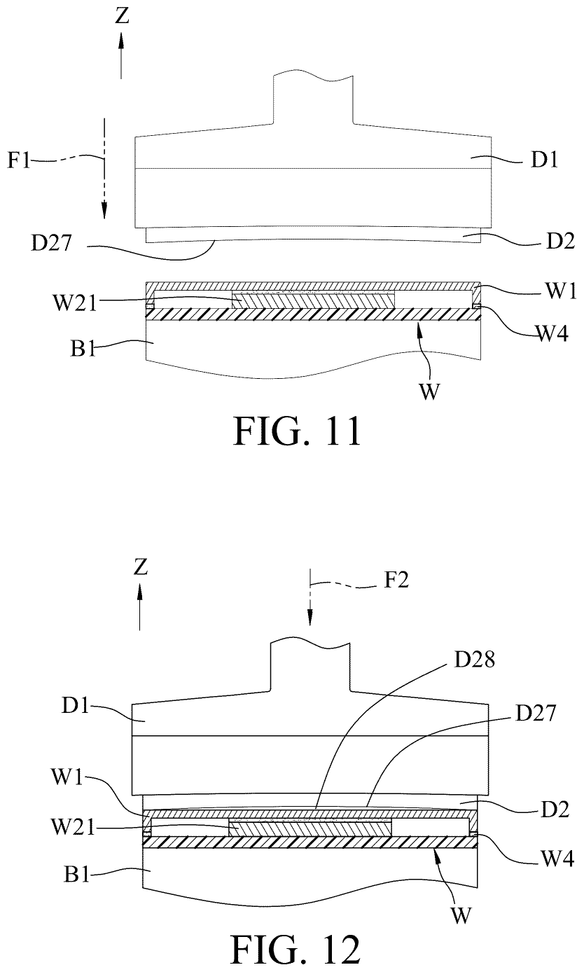

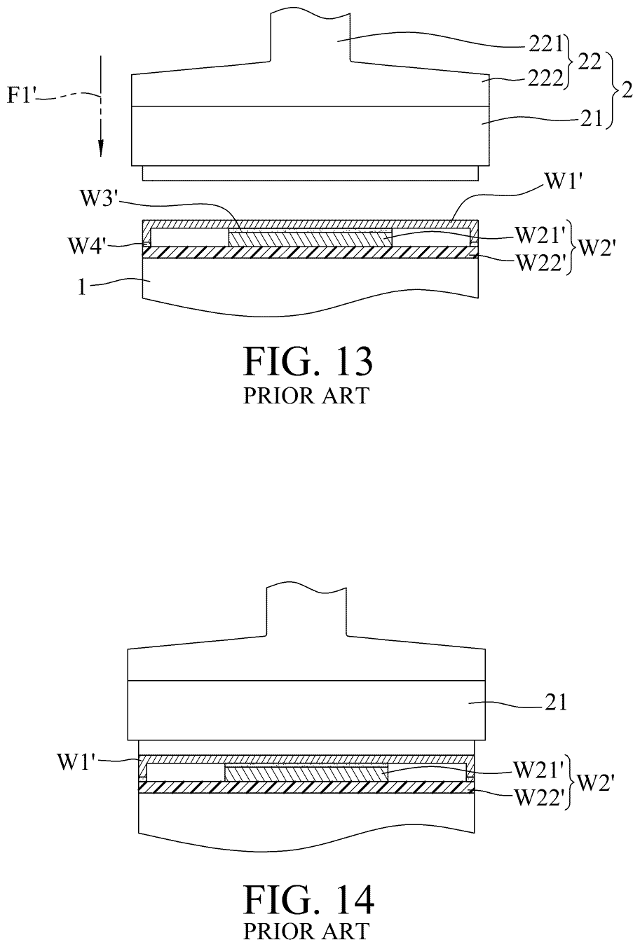

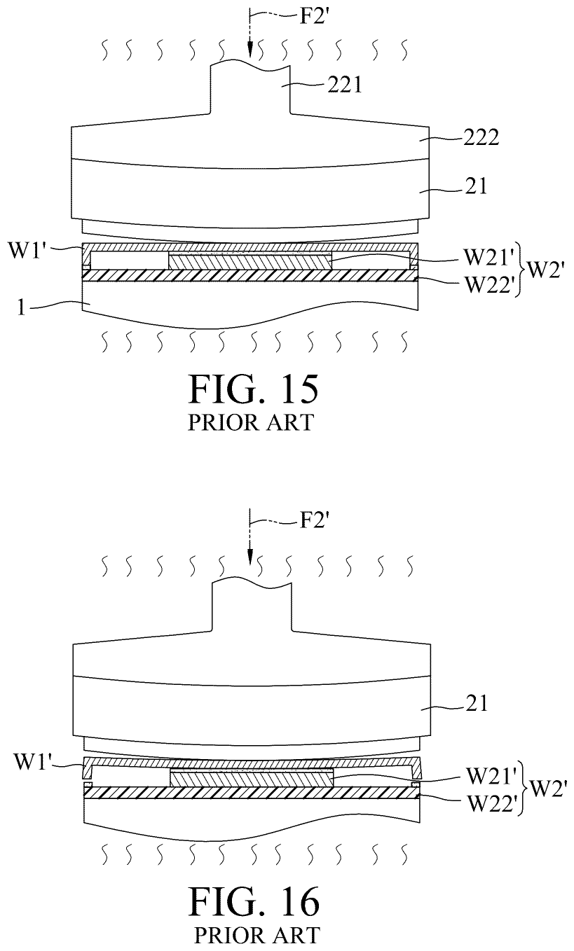

It should be noted that, referring to FIG. 11, the pressing block (D2) is made of a deformable material and thus the pressing block (D2) is slightly deformable when subjected to external forces. In this embodiment, the pressing rod (D1) may be made of a metal material such as steel, and the pressing block (D2) may be made of a plastic material such as polyetherimide (PEI) and ceramic materials such as silicon carbide (SiC) ceramic or alumina (Al₂O₃) ceramic, but the present disclosure is not limited to this example.

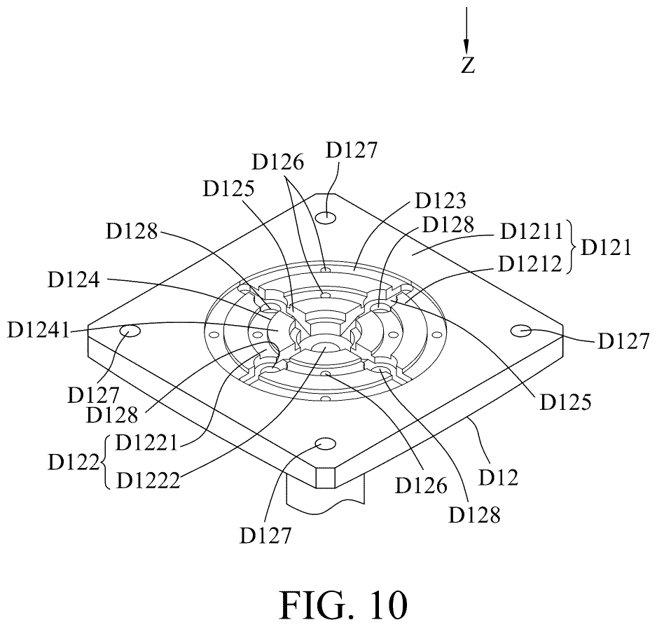

Referring back to FIGS. 7 to 10, the press rod unit (D) further includes at least one fixing member (D3) and at least one adjusting member (D4) for fastening the pressing block (D2) to the pressing rod (D1).

The rod body (D11) of the pressing rod (D1) is formed with an air passage (D111) extending in the up-down direction (Z). The pressing seat (D12) has a connecting surface (D121) for fixedly mounting of the pressing block (D2) thereto and a sunken portion (D122) for accommodation of the pressing block (D2) when the pressing block (D2) is deformed. The pressing block (D2) is deformable to partially extend into the sunken portion (D122).

The connecting surface (D121) is disposed on an outer periphery of the sunken portion (D122) and is divided by an annular groove (D123) into an outer connecting surface (D1211) and an inner connecting surface (D1212) surrounded by the annular groove (D123) and the outer connecting surface (D1211). The outer connecting surface (D1211) and the inner connecting surface (D1212) have the same height in the up-down direction (Z). The sunken portion (D122) is a circular portion, is formed in a central portion of the pressing seat (D12), and is recessed toward the rod body (D11). The sunken portion (D122) is divided by an annular rib (D124) into an outer sunken portion (D1221), and an inner sunken portion (D1222) surrounded by the annular rib (D124) and the outer sunken portion (D1221) and in spatial communication with the air passage (D111). The annular rib (D124) has a rib surface (D1241) facing the pressing block (D2), and higher than the outer connecting surface (D1211) and the inner connecting surface (D1212) in the up-down direction (Z). In this embodiment, a height difference in the up-down direction (Z) between the rib surface (D1241) and each of the outer connecting surface (D1211) and the inner connecting surface (D1212) is designed according to a specification of the to-be-pressed objects (W), and the height difference ranges from 0.1 mm to 2 mm.

The pressing seat (D12) further includes at least one channel (D125) in spatial communication with the annular groove (D123), the outer sunken portion (D1221), and the inner sunken portion (D1222). In this embodiment, the pressing seat (D12) includes two channels (D125) that are arranged in a cross shape.

The pressing seat (D12) further includes a plurality of through holes (D126) formed therethrough in the up-down direction (Z) for ventilation. Some of the through holes (D126) are in spatial communication with the annular groove (D123), and the remaining ones of the through holes (D126) are in spatial communication with the outer sunken portion (D1221). Air may be introduced into the air passage (D111), and flows outwardly through the through holes (D126) to facilitate heat dissipation of the pressing seat (D12).

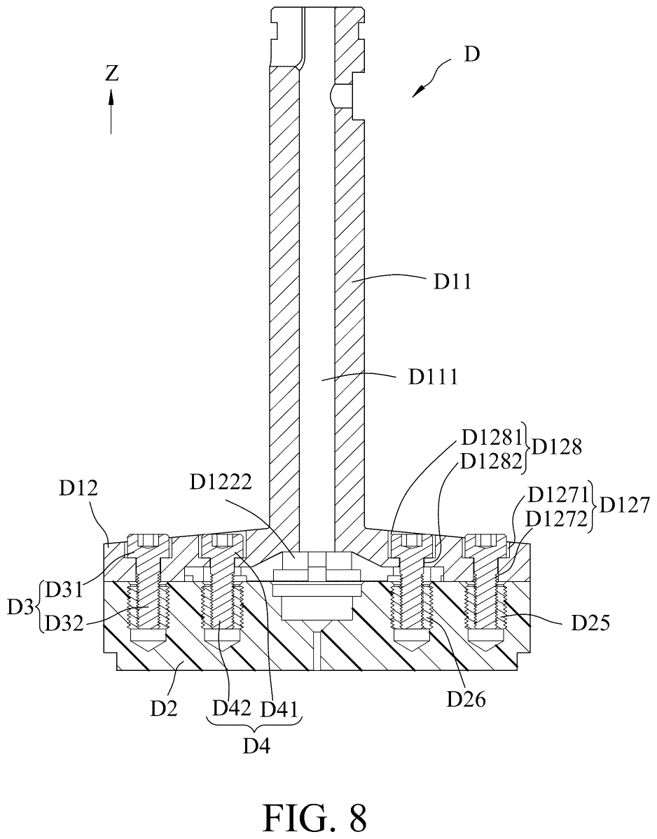

The pressing seat (D12) further includes at least one first through hole (D127) for extension of the at least one fixing member (D3) thereinto and at least one second through hole (D128) for extension of the at least one adjusting member (D4) thereinto. In this embodiment, there are four fixing members (D3) extending respectively through four first through holes (D127) that are arranged at four corners of the pressing seat (D12), and four adjusting members (D4) extending respectively into four second through holes (D128) that are arranged at an outer periphery of the rod body (D11). As shown in FIG. 8, each of the first through holes (D127) has a first upper portion (D1271) and a first lower portion (D1272) disposed lower than the first upper portion (D1271) in the up-down direction (Z) and having a diameter smaller than a diameter of the first upper portion (D1271). Each of the second through holes (D128) has a second upper portion (D1281) and a second lower portion (D1282) disposed lower than the second upper portion (D1281) in the up-down direction (Z) and having a diameter smaller than a diameter of the second upper portion (D1281). The first through holes (D127) correspond in position to, e.g., are formed in, the outer connecting surface (D1211) of the connecting surface (D121), and the second through holes (D128) correspond in position to, e.g., are formed in, the outer sunken portion (D1221).

The pressing block (D2) has a connecting portion (D21) corresponding to the connecting surface (D121) and a deformable portion (D22) corresponding in position to the sunken portion (D122). The connecting portion (D21) is disposed on an outer periphery of the deformable portion (D22). The pressing block (D2) also includes at least one first threaded sleeve (D25) and at least one second threaded sleeve (D26). In this embodiment, there are four first threaded sleeves (D25) respectively corresponding in position to the first through holes (D127) and disposed in the connecting portion (D21), and four second threaded sleeves (D26) respectively corresponding in position to the second through holes (D128) and disposed in the deformable portion (D22). Each of the first threaded sleeve (D25) defines a first screw hole (D23) registered with the respective one of the first through holes (D127) in the up-down direction (Z), and each of the second threaded sleeves (D26) defines a second screw hole (D24) registered with the respective one of the second through holes (D128) in the up-down direction (Z).

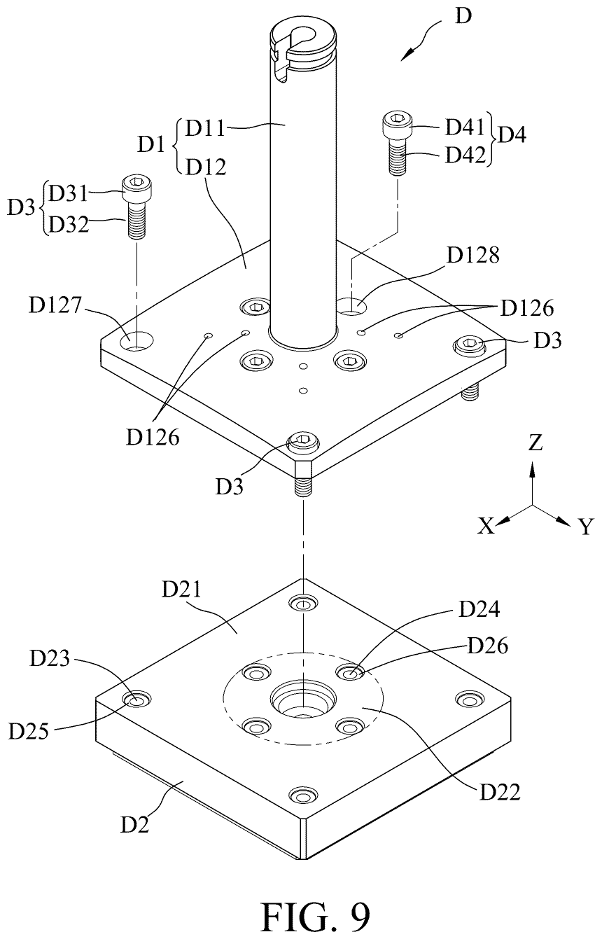

As shown in FIGS. 8 and 9, each of the fixing members (D3) has a fixing head (D31) and a fixing body (D32) having a threaded outer surface and a diameter smaller than a diameter of the fixing head (D31). Each of the fixing members (D3) extends into the respective one of the first through holes (D127) and the fixing body (D32) thereof engages the first screw hole (D23) of the respective one of the first threaded sleeves (D25).

Each of the adjusting members (D4) has an adjusting head (D41) and an adjusting body (D42) having a threaded outer surface and a diameter smaller than a diameter of the adjusting head (D41). Each of the adjusting members (D4) extends into the respective one of the second through holes (D128) and the adjusting body (D42) engages the second screw hole (D24) of the respective one of the second threaded sleeves (D26).

The connecting portion (D21) of the pressing block (D2) is connected to the connecting surface (D121) by the four fixing members (D3). The four adjusting members (D4) are operable to adjust a degree of deformation of the deformable portion (D22) of the pressing block (D2), i.e., an extent to which the pressing block (D2) extends into the sunken portion (D122). In this embodiment, the fixing members (D3) and the adjusting members (D4) are screws, but the present disclosure is not limited to this example.

In the following description, since the structures of the fixing members (D3) are identical, the structures of the first through holes (D127) are identical, and the structures of the first threaded sleeves (D25) are identical, only one of the fixing members (D3), the respective one of the first through holes (D127), and the respective one of the first threaded sleeves (D25) are described for the sake of brevity. To assemble the press rod unit (D), the fixing member (D3) is brought to extend into the first lower portion (D1272) of the first through hole (D127), and threadedly engages the first screw hole (D23). At this time, the fixing head (D31) of the fixing member (D3) is inserted into the first upper portion (D1271) of the first through hole (D127). The fixing member (D3) provides a force for the connecting portion (D21) to be connected to the connecting surface (D121), thereby fastening the pressing block (D2) to the pressing seat (D12).

In the following description, since the structures of the adjusting members (D4) are identical, the structures of the second through holes (D128) are identical, and the structures of the second threaded sleeves (D26) are identical, only one of the adjusting members (D4), the respective one of the second through holes (D128), and the respective one of the second threaded sleeves (D26) are described for the sake of brevity. Next, the adjusting member (D4) is brought to extend into the second lower portion (D1282) of the second through hole (D128), and threadedly engages the second screw hole (D24). At this time, the adjusting head (D41) of the adjusting members (D4) is inserted into the second upper portion (D1281) of the second through hole (D128). The adjusting member (D4) provides a force for the deformable portion (D22) to deform and extend into the sunken portion (D122). That is to say, the deformable portion (D22) is pulled upwardly relative to the connecting portion (D21) in the up-down direction (Z) to deform and extend into the sunken portion (D122). It should be noted that a depth of the adjusting member (D4) extending into the second screw hole (D24) is adjustable to change the degree of deformation of the deformable portion (D22). The deeper the adjusting member (D4) extends into, e.g., screws into, the second through hole (D128), the greater the degree of deformation of the deformable portion (D22). The deformable portion (D22) may be pulled upwardly until the deformable portion (D22) is in contact with the rib surface (D1241) of the annular rib (D124). Since the connecting portion (D21) is disposed on and fixed onto the outer periphery of the deformable portion (D22), when the deformable portion (D22) is pulled up, a central bottom portion of the pressing block (D2) is deformed to form a concave surface (D27) (see FIG. 11) facing downwardly in the up-down direction (Z). That is to say, the outer periphery of the pressing block (D2) is lower than the central bottom portion of the pressing block (D2) in the up-down direction (Z).

Before the press apparatus of the embodiment of the present disclosure performs pressing operation, the boat (S) carrying the to-be-pressed objects (W) is first conveyed to the operating space (C6) to be disposed between the upper mold assembly (A) and the lower mold assembly (B), and is then placed on the lower mold assembly (B), such that the lower mold modules (B1) of the lower mold assembly (B) extending respectively through the slots (S2) of the boat (S) respectively support the integrated circuit components (W2) of the to-be-pressed objects (W) thereon. In the following description, since the structures of the to-be-pressed objects (W) are identical, and the structures of the lower mold modules (B1) are identical, only one of the to-be-pressed objects (W) and the respective one of the lower mold modules (B1) will be described for the sake of brevity.

When using the press apparatus of the present disclosure to press the to-be-pressed object (W), the upper mold assembly (A) is moved downwardly by the first driving force (F1), and the pressing block (D2) formed with the concave surface (D27) presses against the lid (W1) of the to-be-pressed object (W). At this time, the outer periphery of the pressing block (D2) presses against an outer periphery of the lid (W1), and the central bottom portion of the pressing block (D2) does not press a central portion of the lid (W1), thereby forming a buffering space (D28) (see FIG. 12) between the concave surface (D27) and the lid (W1). Specifically, the pressing block (D2) formed with the concave surface (D27) presses against the lid (W1) at a position above the adhesive materials (W4), and does not press against the lid (W1) at a position above the chip (W21).

Next, the press rod unit (D) of the upper mold assembly (A) is moved downwardly by the second driving force (F2), and the pressing block (D2) formed with the concave surface (D27) exerts a pressing force on the lid (W1) to facilitate connection of the outer periphery of the lid (W1) to the substrate (W22), and reduce the possibility of damage to the chip (W21). It should be noted that during the pressing process, a heater (not shown) may be disposed on the pressing block (D2) and/or the lower mold module (B1) to heat up the lid (W1) and/or the substrate (W22) of integrated circuit component (W2). Since the main feature of the present disclosure does not reside in the structure of the heater, further details of the same are omitted for the sake of brevity.

It should be noted that in the embodiment of the present disclosure, the numbers of pressing mold mechanisms (A11) of the upper mold module (A1) and the pressing rod drivers (A21) of the driver device (A2) are plural, but the numbers of each of the pressing mold mechanism (A11) and the pressing rod driver (A21) may be one.

In summary, in the press apparatus of the embodiment according to the present disclosure, by virtue of the design of the press rod unit (D), the pressing block (D2) is deformed to form the concave surface (D27) facing downwardly to facilitate bonding of the outer periphery of the lid (W1) to the substrate (W22) and reduce the possibility of damage to the chip (W21) during the pressing process. Thus, a relatively good packaging quality may be provided.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A press rod unit, comprising:
a pressing rod that includes a rod body and a pressing seat disposed at one end of said rod body and having a connecting surface and a sunken portion;
a pressing block that is disposed on said connecting surface of said pressing seat and that is deformable to partially extend into said sunken portion;
at least one fixing member that fastens said pressing block to said connecting surface; and
at least one adjusting member that is operable for adjusting a degree of deformation of said pressing block in said sunken portion.

2. The press rod unit as claimed in claim 1, wherein:
said pressing block includes a connecting portion corresponding in position to said connecting surface and a deformable portion corresponding in position to said sunken portion; and
said connecting portion is disposed on an outer periphery of said deformable portion.

3. The press rod unit as claimed in claim 2, wherein:
said at least one fixing member provides a force for said connecting portion to be connected to said connecting surface; and
said at least one adjusting member provides a force for said deformable portion to deform and extend into said sunken portion.

4. The press rod unit as claimed in claim 2, wherein said deformable portion is pulled upwardly relative to said connecting portion in an up-down direction to deform and extend into said sunken portion.

5. The press rod unit as claimed in claim 1, wherein said pressing rod is made of a metal material, and said pressing block is made of one of a plastic material and a ceramic material.

6. The press rod unit as claimed in claim 1, wherein:
said pressing seat further has at least one first through hole for extension of said at least one fixing member thereinto, and at least one second through hole for extension of said at least one adjusting member thereinto;
said pressing block further has at least one first screw hole registered with said at least one first through hole in an up-down direction, and at least one second screw hole registered with said at least one second through hole in the up-down direction;
said at least one fixing member extends through said at least one first through hole to engage said at least one first screw hole; and
said at least one adjusting member extends through said at least one second through hole to engage said at least one second screw hole.

7. The press rod unit as claimed in claim 6, wherein said at least one first through hole and said at least one first screw hole correspond in position to said connecting surface, and said at least one second through hole and said at least one second screw hole correspond in position to said sunken portion.

8. An upper mold assembly comprising:
an upper mold module that includes at least one press mold mechanism, and an upper mold seat for mounting of said at least one press mold mechanism;
wherein said at least one press mold mechanism includes said press rod unit as claimed in Claim 1.

9. The upper mold assembly as claimed in claim 8, wherein:
said upper mold assembly further comprises a driver device including at least one pressing rod driver registered with said at least one press mold mechanism in an up-down direction; and
said at least one pressing rod driver is operable to drive said press rod unit of said at least one press mold mechanism to move relative to said upper mold seat in the up-down direction.

10. The upper mold assembly as claimed in claim 8, wherein:
said pressing block includes a connecting portion corresponding in position to said connecting surface and a deformable portion corresponding in position to said sunken portion; and
said connecting portion is disposed on an outer periphery of said deformable portion.

11. The upper mold assembly as claimed in claim 10, wherein said deformable portion is pulled upwardly relative to said connecting portion in an up-down direction to deform and extend into said sunken portion.

12. The upper mold assembly as claimed in claim 8, wherein said pressing rod is made of a metal material, and said pressing block is made of one of a plastic material and a ceramic material.

13. The upper mold assembly as claimed in claim 8, wherein:
said pressing seat further has at least one first through hole for extension of said at least one fixing member thereinto, and at least one second through hole for extension of said at least one adjusting member thereinto;
said pressing block further has at least one first screw hole registered with said at least one first through hole in an up-down direction, and at least one second screw hole registered with said at least one second through hole in the up-down direction;
said at least one fixing member extends through said at least one first through hole to engage said at least one first screw hole; and
said at least one adjusting member extends through said at least one second through hole to engage said at least one second screw hole.

14. The upper mold assembly as claimed in claim 13, wherein said at least one first through hole and said at least one first screw hole correspond in position to said connecting surface, and said at least one second through hole and said at least one second screw hole correspond in position to said sunken portion.

15. A press apparatus adapted for pressing at least one to-be-pressed object including an integrated circuit component and a lid that covers the integrated circuit component, said press apparatus comprising:
a lower mold assembly that includes at least one lower mold module adapted for supporting the integrated circuit component thereon; and
an upper mold assembly that includes at least one press rod unit as claimed in claim 1;
said pressing block of said at least one press rod unit being adapted for pressing the lid of the at least one to-be-pressed object toward the integrated circuit component.

16. The press apparatus as claimed in claim 15, wherein:
said pressing block includes a connecting portion corresponding in position to said connecting surface and a deformable portion corresponding in position to said sunken portion; and
said connecting portion is disposed on an outer periphery of said deformable portion.

17. The press apparatus as claimed in claim 16, wherein said deformable portion is pulled upwardly relative to said connecting portion in an up-down direction to deform and extend into said sunken portion.

18. The press apparatus as claimed in claim 15, wherein said pressing rod is made of a metal material, and said pressing block is made of one of a plastic material and a ceramic material.

19. The press apparatus as claimed in claim 15, wherein:
said pressing seat further has at least one first through hole for extension of said at least one fixing member thereinto, and at least one second through hole for extension of said at least one adjusting member thereinto;
said pressing block further has at least one first screw hole registered with said at least one first through hole in an up-down direction, and at least one second screw hole registered with said at least one second through hole in the up-down direction;
said at least one fixing member extends through said at least one first through hole to engage said at least one first screw hole; and
said at least one adjusting member extends through said at least one second through hole to engage said at least one second screw hole.

20. The press apparatus as claimed in claim 19, wherein said at least one first through hole and said at least one first screw hole correspond in position to said connecting surface, and said at least one second through hole and said at least one second screw hole correspond in position to said sunken portion.
